(19) United States
(12) Patent Application Publication
(10) Pub. No.: US 2020/0135962 A1
(43) Pub. Date: Apr. 30, 2020

(54) SYSTEMS AND METHODS FOR FABRICATING PHOTOVOLTAIC DEVICES VIA REMOTE EPITAXY

(71) Applicants: Massachusetts Institute of Technology, Cambridge, MA (US); Khalifa University of Science and Technology, Abu Dhabi (AE)

(72) Inventors: Kyusang Lee, Crozet, VA (US); Jeehwan Kim, Cambridge, MA (US); Ibraheem Almansouri, Abu Dhabi (AE)

(73) Assignees: Massachusetts Institute of Technology, Cambridge, MA (US); Khalifa University of Science and Technology, Abu Dhabi (AE)

(21) Appl. No.: 16/606,650

(22) PCT Filed: Apr. 20, 2018
(86) PCT No.: PCT/US2018/028553

§ 371 Date: Oct. 18, 2019

Related U.S. Application Data
(60) Provisional application No. 62/488,124, filed on Apr. 21, 2017.

(51) Int. Cl. H01L 31/18; H01L 31/0445; H01L 31/0735; H01L 21/02

(52) U.S. Cl. CPC H01L 31/1844; H01L 31/0445; H01L 21/02293; H01L 31/1896; H01L 31/0735

(57) ABSTRACT

A method of fabricating a photovoltaic (PV) device includes forming a release layer comprising a two-dimensional (2D) material on a first substrate having a first lattice constant and epitaxially growing a first PV layer on the release layer using the first substrate as a seed. The first PV layer has a second lattice constant substantially equal to the first lattice constant of the first substrate. The method also includes removing the first PV layer from the release layer and epitaxially growing a second PV layer on the release layer.

### CROSS-REFERENCE TO RELATED APPLICATIONS

This application claims the priority benefit under 35 U.S.C. § 119(e) of U.S. Application No. 62/488,124, filed Apr. 21, 2017, entitled “FABRICATION OF LOW-COST COMPOUND SEMICONDUCTOR PHOTOVOLTAICS VIA REMOTE EPITAXY AND TWO-DIMENSIONAL LAYER TRANSFER,” which is hereby incorporated herein by reference in its entirety.

### BACKGROUND

Due to the abundance of sunlight, solar photovoltaic (PV) technology that converts sunlight directly into electricity is one of the most promising sources of alternative energy. In order to compete with conventional sources of energy (e.g., fossil fuel), it is desirable for PV cells to have high power conversion efficiency (PCE) and low manufacturing cost. However, the compound semiconductor PV cells that exhibit the highest PCE (e.g., about 44% or greater), such as multi junction PV cells, usually suffer from prohibitive production costs (e.g., more than $50,000/m²). On the other hand, poly-crystalline Si or thin-film solar cells, such as copper indium gallium selenide (CIGS) and CdTe cells, can have a low production cost at about $200/m², but their PCE is usually around 15% to 20%.

### SUMMARY

Embodiments of the present invention include apparatus, systems, and methods for fabricating photovoltaic devices via remote epitaxy. In one example, a method of fabricating a photovoltaic (PV) device includes forming a release layer comprising a two-dimensional (2D) material on a first substrate having a first lattice constant and epitaxially growing a first PV layer on the release layer using the first substrate as a seed. The first PV layer has a second lattice constant substantially equal to the first lattice constant of the first substrate. The method also includes removing the first PV layer from the release layer and epitaxially growing a second PV layer on the release layer.

In another example, a method of fabricating a PV device includes forming a graphene monolayer on a first substrate having a first lattice constant and epitaxially growing a first emitter layer on the release layer using the first substrate as a seed. The method also includes epitaxially growing a first base layer on the first emitter layer to form a first PV layer. The first PV layer has a second lattice constant substantially equal to the first lattice constant of the first substrate. The method also includes transferring the first PV layer to a host substrate such that the first emitter layer is oriented to receive incident light for generating electricity and epitaxially growing a second PV layer on the release layer.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIGS. 1A-1F illustrate a method of fabricating a photovoltaic (PV) device via remote epitaxy and two-dimensional (2D) layer transfer.

FIGS. 2A-2B illustrate a method of fabricating a PV device including a stack of PV layers.

FIGS. 3A-3G illustrate a method of fabricating GaAs solar cells using remote epitaxy and 2D layer transfer.

FIGS. 4A-4E illustrate a method of fabricating multi junction solar cells using remote epitaxy and 2D layer transfer.

### DETAILED DESCRIPTION

Overview

Systems and methods described herein employ an approach to manufacture highly efficiently photovoltaic (PV) devices at low cost. This approach is based on remote epitaxy and two-dimensional (2D) layer transfer. In this approach, a PV layer is epitaxially grown on a release layer, which may or may not be lattice-matched to the PV layer and is disposed in turn on a substrate (also referred to as a growth substrate) that is lattice-matched to the PV layer. The release layer is made of a 2D material to support van der Waals epitaxy (VDWE), in which the PV layer has only van der Waals interactions with the underlying release layer. As understood in the art, a van der Waals interaction is not a chemical bond between two materials. Instead, it originates from the dipole interactions between atoms. Compared to ionic or covalent bonding, the van der Waals force is much weaker. As a result, when the PV layer is deposited on the release layer, the PV layer grows unstrained and forms a lattice having the lattice constant that is identical to its bulk lattice constant.

In remote epitaxy, the epitaxial registry of adatoms can be remotely assigned by the underlying growth substrate via modulating the distance between the growth substrate and the PV layer (this distance is also referred to as the interaction gap). In other words, the growth substrate, although physically separated from the PV layer by the release layer, can have a significant orienting effect on the PV layer during epitaxial growth if the release layer is thin enough (e.g., several atoms thick). The grown PV layer can then be readily released from the release layer, thereby allowing multiple uses of the growth substrate and reducing the manufacturing cost.

Methods of Fabricating Photovoltaic (PV) Devices Via Remote Epitaxy

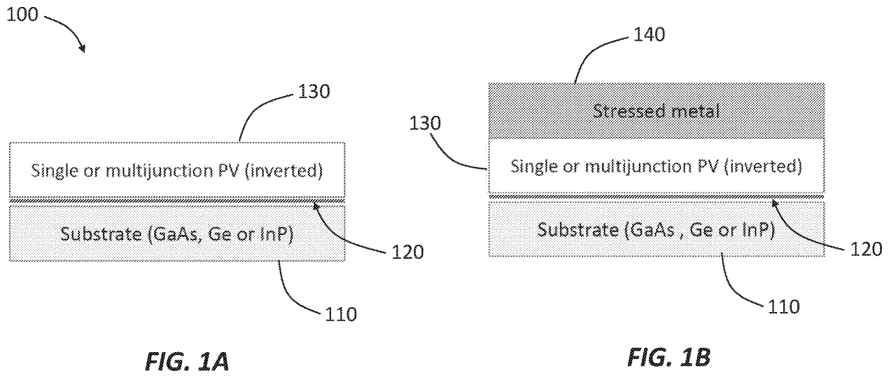

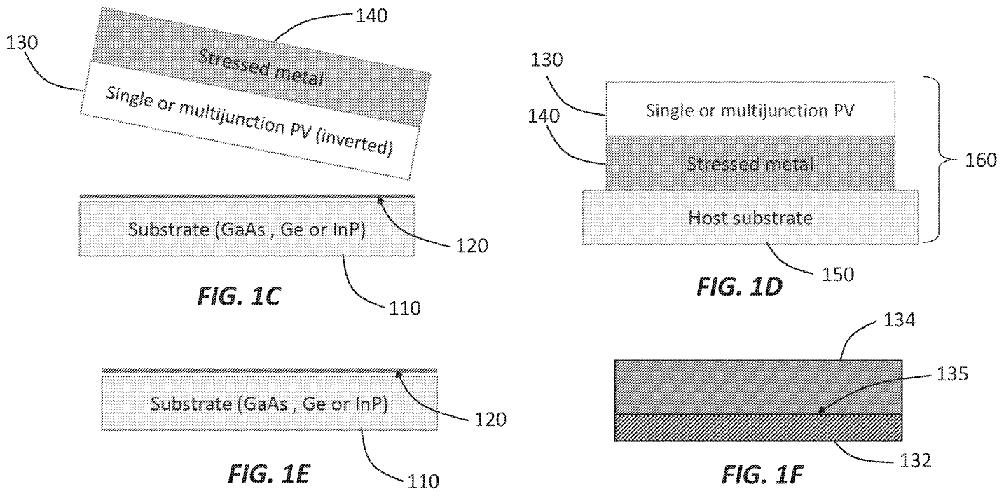

FIGS. 1A-1F illustrate a method 100 of fabricating a PV device via remote epitaxy and 2D layer transfer. The method 100 includes forming a single-junction or multi junction PV layer 130 on a release layer 120, which is disposed on a growth substrate 110, as illustrated in FIG. 1A. The growth substrate 110 is usually in crystalline form and has a first lattice constant. The release layer 120 includes a 2D material such that the interaction between the release layer 120 and the PV layer 130 is dominated by van der Waals forces. In addition, the thickness of the release layer 120 is less than a threshold value (e.g., about 1 nm or less) so as to allow the field of the growth substrate 110 to guide the epitaxial growth of the PV layer 130. Therefore, the PV layer 130 can be in a single-crystalline form having a second lattice constant substantially equal to the first lattice constant of the growth substrate.

FIG. 1B shows a stressor 140 is disposed on the PV layer 130. For example, the stressor 140 can include a high-stress metal film, such as a Ni film. In this example, the Ni stressor 140 can be deposited on the PV layer 130 in an evaporator at a vacuum level of 1×10⁻⁵ Torr. An optional tape layer can be disposed on the stressor 140 to facilitate handling of the stressor 140 and the PV layer 130. The tape and the stressor 140 can be used to mechanically exfoliate the PV layer 130 from the release layer 120 by applying high strain energy to the interface between the PV layer 130 and the release layer 120, as illustrated in FIG. 1C. The release rate can be fast at least due to the weak van der Waals bonding between the 2D material in the release layer 120 and other materials in the PV layer 130.

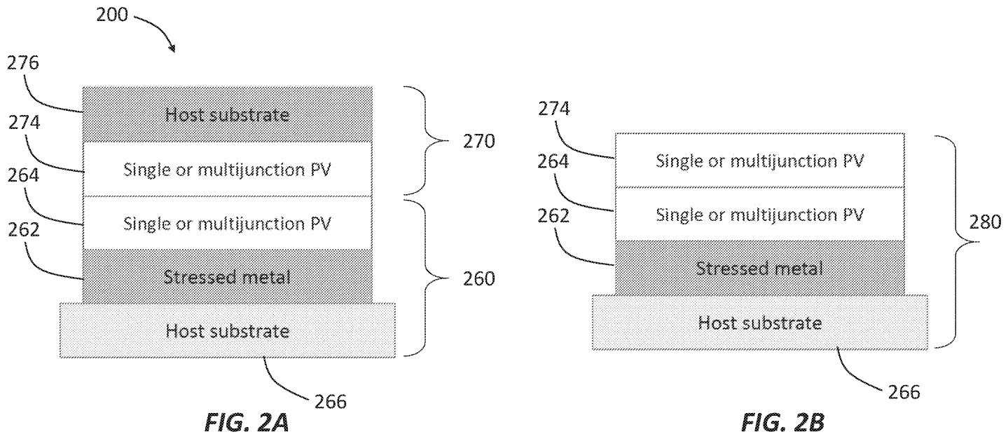

In FIG. 1D, the released PV layer 130 is disposed on a host substrate 150 to form a semiconductor device 160. Further processing of the semiconductor device 160 can include, for example, etching, deposition, and bonding. The host substrate 150 can include various types of materials, such as silicon, glass, and plastic, among others. In one example, the host substrate 150 is employed as a holder to hold the PV layer 130 for further processing. In another example, the host substrate 150 can include another PV layer such that the device 160 can include tandem solar cells. For example, each solar cell in the tandem solar cells can have a distinct band gap, thereby absorbing incident light within different spectral regions so as to increase the power conversion efficiency of the device 160 (see more details with reference to FIGS. 2A and 2B).

In yet another example, the host substrate 150 can include a metal substrate or a substrate having a metal surface. The PV layer 130 can be attached to the metal substrate or metal surface via various metallic bonding techniques, such as cold welding, eutectic bonding, and thermo-compression bonding, among others. In this example, the host substrate 150 can function as an electrode for the device 160. Alternatively or additionally, the host substrate 150 can function as a back reflector.

In one example (as illustrated in FIG. 1D), the stressor 140 is put in contact with the host substrate 150 to form the device 160. In this case, the stressor 140 can also function as an electrode for the device 160. In addition, the PV layer 130 can be inverted immediately after epitaxial growth (as illustrated in FIG. 1A) such that after transferring, which may flip the PV layer 130, the PV layer 130 has the proper orientation. For example, FIG. 1F shows that the PV layer 130 includes an emitter layer 132 closer to the release layer 120 and a base layer 134 formed on the emitter layer 132. A PN junction can be defined at the interface between the emitter layer 132 and the base layer 134. After transferring, as shown in FIG. 1D, the PV layer 130 is flipped upside down such that the emitter layer 132 is above the base layer 134 to receive incident radiation for electricity generation.

In another example, after the PV layer 130 is placed on the host substrate 150, the stressor 140 can be removed by, for example, etching with a FeCl₃-based solution. In this example, the PV layer 130 can be placed directly in contact with the host substrate 150.

In the method 100, after the release of the PV layer 130 shown in FIG. 1C, the remaining platform including the growth substrate 110 and the release layer 120 can be reused in the next cycle of epilayer fabrication, as shown in FIG. 1E. Alternatively, the release layer 120 can also be removed. In this case, a new release layer can be disposed on the growth substrate 110 before next cycle of epilayer fabrication. In either case, the release layer 120 protects the growth substrate 110 from damage, thereby allowing multiple uses of the growth substrate 110 and reducing the cost of fabricating the semiconductor device 160.

Various types of 2D materials can be used for the release layer 120. In one example, the release layer 120 includes graphene (e.g., monolayer graphene or multilayer graphene). In another example, the release layer 120 includes one or more transition metal dichalcogenide (TMD) monolayers, which are atomically thin semiconductors of the type MX₂, with M being a transition metal atom (e.g., Mo, W, etc.) and X being a chalcogen atom (e.g., S, Se, or Te). In a TMD lattice, one layer of M atoms is usually sandwiched between two layers of X atoms. In yet another example, the release layer 120 can include a single-atom layer of metal, such as silver, palladium, and rhodium. In yet another example, the release layer 120 can include planar organic molecules.

In one example, the release layer 120 can be directly fabricated on the growth substrate 110. For example, the release layer 120 can include planar organic molecules that can be deposited on the growth substrate 110 via evaporation. In another example, the release layer 120 can be prepared on another substrate and then transferred to the growth substrate 110. For example, the release layer 120 can include graphene and can be formed on a silicon carbide substrate before being transferred to the growth substrate 110.

When graphene is used, the release layer 120 can be prepared via various methods. In one example, the release layer 120 can include epitaxial graphene grown on a (0001) 4H-SiC wafer with a silicon surface. The fabrication of the release layer 120 can include a multistep annealing process. A first annealing step can be performed in H₂ gas for surface etching, and a second annealing step can be performed in Ar for graphitization at high temperature (e.g., about 1,575° C.). In another example, the release layer 120 can be grown on a substrate via a chemical vapor deposition (CVD) process. The substrate can include a nickel substrate or a copper substrate. Alternatively, the substrate can include an insulating substrate of SiO₂, HfO₂, Al₂O₃, Si₃N₄, and practically any other high temperature compatible planar material by CVD.

Various methods can also be used to transfer the graphene release layer 120 to the growth substrate 110. In one example, a carrier film can be attached to the graphene release layer 120. The carrier film can include a thick film of Poly(methyl methacrylate) (PMMA) or a thermal release tape and the attachment can be achieved via a spin-coating process. After the combination of the carrier film and the graphene release layer 120 is disposed on the growth substrate 110, the carrier film can be dissolved (e.g., in acetone) for further fabrication of the PV layer 130 on the graphene release layer 120.

In another example, a stamp layer including an elastomeric material, such as polydimethylsiloxane (PDMS), can be attached to the graphene release layer 120. The substrate for growing graphene can be etched away, leaving the combination of the stamp layer and the graphene release layer 120. After the stamp layer and the graphene release layer 120 are placed on the growth substrate 110, the stamp layer can be removed by mechanical detachment, producing a clean surface of the graphene release layer 120 for further processing.

In yet another example, a self-release transfer method can be used to transfer the graphene release layer 120 to the growth substrate 110. In this method, a self-release layer is first spun-cast over the graphene release layer 120. An elastomeric stamp is then placed in conformal contact with the self-release layer. The substrate for growing graphene can be etched away to leave the combination of the stamp layer, the self-release layer, and the graphene release layer 120. After this combination is placed on the growth substrate 110, the stamp layer can be removed mechanically and the self-release layer can be dissolved under mild conditions in a suitable solvent. The self-release layer can include polystyrene (PS), poly(isobutylene) (PIB), or Teflon AF (poly[4,5-difluoro-2,2-bis(trifluoromethyl)-1,3-dioxole-co-tetrafluoroethylene]). More details of using graphene in the release layer 120 can be found in PCT Publication No. WO 2017/044577, filed Sep. 8, 2016, entitled “SYSTEMS AND METHODS FOR GRAPHENE BASED LAYER TRANSFER,” which is hereby incorporated herein by reference in its entirety.

The fabrication of the PV layer 130 can be carried out using any suitable semiconductor fabrication technique known in the art. For example, low-pressure Metal-Organic Chemical Vapor Deposition (MOCVD) can be used to grow the PV layer 130 (e.g., a GaN film) on the release layer 120. In this example, the release layer 120 and the growth substrate 110 can be baked (e.g., under H₂ for >15 min at >1,100° C.) to clean the surface. Then the deposition of the PV layer 130 including GaN can be performed at, for example, 200 mbar. Trimethylgallium, ammonia, and hydrogen can be used as the Ga source, nitrogen source, and carrier gas, respectively. A modified two-step growth can be employed to obtain flat GaN epitaxial films on the release layer 120. The first step can be carried out at a growth temperature of 1,100° C. for few minutes where guided nucleation at terrace edges can be promoted. The second growth step can be carried out at an elevated temperature of 1,250° C. to promote the lateral growth. Vertical GaN growth rate in this case can be around 20 nm per min.

The PV layer 130 includes one or more materials for PV applications, such as silicon, germanium, GaAs, InP, InGaP, GaInAsP, GaInAs, and InGaAs, among others. In addition, the PV layer 130 can also include one or more PN junctions to facilitate PV applications. For example, the PV layer 130 can include an emitter layer (e.g., an N-doped region), a base layer (e.g., a P-doped region), and a PN junction between the emitter layer and the base layer. In one example, the doping of the PV layer 130 can be carried out simultaneously with the epitaxial growth of the PV layer 130. For example, in chemical vapor deposition (CVD), changing the composition of the element source gases (e.g., including or removing doping elements, such as silicon, carbon, or phosphorous) can change the doping of the resulting epitaxial layer. The doping can also be introduced after the epitaxial growth of each sub-layer via ion implantation.

In one example, the PV layer 130 includes a single-junction PV cell, such as a GaAs PV cell or an InP PV cell. In another example, the PV layer 130 includes a multi junction PV cell, such as a GaAs/InGaP double-junction PV cell, a GaInAsP/GaInAs double-junction PV cell, an InGaAs/GaAs/InGaP triple-junction PV cell, an InGaP/GaAs/GaInAsP/GaInAs four-junction PV cell, or an InP/InGaAs double junction PV cell. In yet another example, the PV layer 130 can include a multi junction cell in which multiple junctions are mechanically stacked together. For example, the PV layer 130 can include a GaAs/InGaP double junction (from GaAs) stacked with InP/InGaAs double junction (from InP) (see more details with reference to FIGS. 2A-2B below).

Methods of Fabricating PV Devices Including a Stack of PV Layers

FIGS. 2A-2B illustrate a method of fabricating PV devices including a stack of PV layers. In this method, a first PV device 260 is bonded to a second PV device 270, as shown in FIG. 2A. The first PV device 260 includes a first PV layer 264 disposed on a stressor 262, which in turn is disposed on a first host substrate 266. The second PV device 270 includes a second PV layer 274 attached to a second host substrate 276. The first PV device 260 and the second PV device 270 can be prepared using the method 100 illustrated in FIGS. 1A-1E. For example, the first PV device 260 can be fabricated following the steps illustrated in FIGS. 1A-1D and the second PV device 270 can be fabricated on the reusable platform shown in FIG. 1E. After the first PV device 260 is bonded to the second PV device 270, the second host substrate 276 can be removed via, for example, selective etching, thereby forming a new PV device 280 including a stack of PV layers, as shown in FIG. 2B. The second host substrate 276 can include various materials, such as polyimide that can be removed by oxygen plasma etching.

In the method 200 illustrated in FIGS. 2A-2B, the second host substrate 276 can function as a handle to facilitate the transfer of the second PV layer 274. Alternatively, the second host substrate 276 can remain part of the device 280. For example, the second host substrate 276 can include a conductive substrate that can function as an electrode for the PV device 280.

The bonding between the first PV device 260 and the second PV device 270 can be achieved via various techniques. In one example, the first PV device 260 can be bonded to the second PV device 270 via direct bonding, also referred to as fusion bonding. In this example, the bonding can be based on chemical bonds between the surfaces of the first PV layer 264 and the second PV layer 274. Before bonding, the contacting surfaces of the first PV layer 264 and the second PV layer 274 can undergo a dry cleaning process, such as plasma treatment or ultraviolet (UV)/ozone cleaning, to remove possible contaminants on the surfaces. Then the first PV device 260 and the second PV device 270 can be pressed against each other at room temperature, followed by annealing at elevated temperatures (e.g., greater than 100° C.).

In another example, the first PV device 260 and the second PV device 270 can be bonded via surface activated bonding (SAB). In this example, the contacting surfaces of the first PV layer 264 and the second PV layer 274 can be activated by argon fast atom bombardment in ultra-high vacuum (UHV) (e.g., about 10⁻⁴ to about 10⁻⁷ Pa). The bombardment can remove adsorbed contaminants and native oxides from the surfaces. The activated surfaces are atomically clean and reactive for formation of direct bonds between the first PV layer 264 and the second PV layer 274 when they are brought into contact (e.g., at room temperature).

In yet another example, the first PV device 260 and the second PV device 270 can be bonded together via eutectic bonding, also referred to as eutectic soldering, in which an intermediate metal layer is disposed between the first PV layer 264 and the second PV layer 274 to facilitate the bonding. The intermediate metal layer can include an alloy having a melting point lower than the melting points of the two PV layers 264 and 274. During bonding, the intermediate metal layer can be melted so as to bond together the first PV device 260 and the second PV device 270. After bonding, the intermediate metal layer can also function as an electrode for the device 280. The intermediate metal layer can be deposited on either the surface of the first PV layer 264 or the surface of the second PV layer 274 by sputtering, dual-source evaporation, or electroplating.

In yet another example, the first PV device 260 and the second device 270 can be bonded together via grid bonding, in which a grid is formed on the contacting surface(s) for bonding. For example, the grid can be made of a metal alloy that can be melted during bonding as described above with respect to eutectic soldering.

In the device 280, the first PV layer 264 and the second PV layer 274 can have different band gaps so as to increase the power conversion efficiency of the device 280. For example, the first PV layer 264 can be configured to absorb light in the red and near infrared region and the second PV layer 274 can be configured to absorb light in the blue and green region. The first PV layer 264 can include GaAs and the second PV layer 274 can include InGaP. Each PV layer 264 or 274 can include a single junction PV cell or a multi junction PV cell. In addition, more than two stacks of PV layers can also be used in the device 280. For example, additional PV layers can be disposed on the second PV layer 274.

Methods of Fabricating GaAs Solar Cells

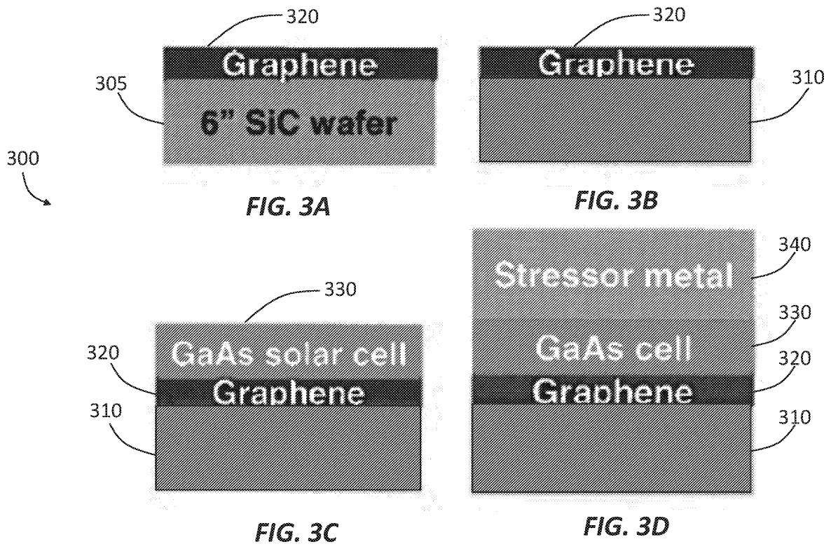

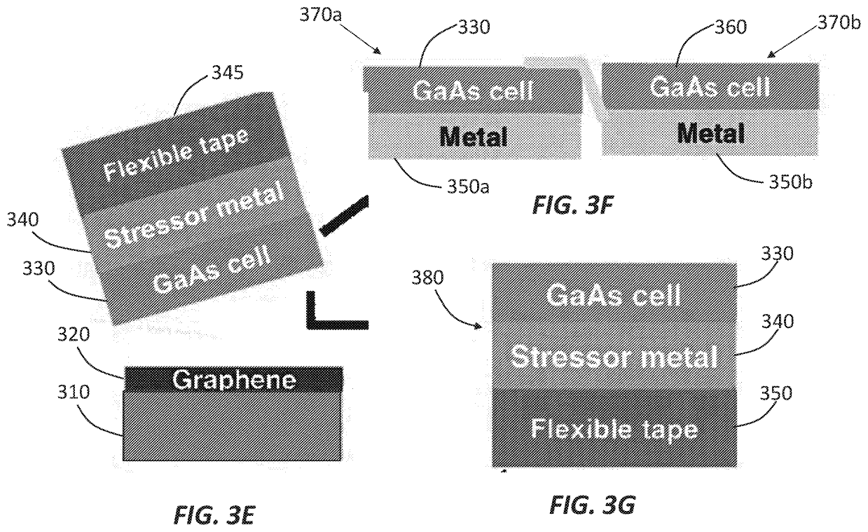

FIGS. 3A-3G illustrate a method 300 of fabricating GaAs solar cells using remote epitaxy and 2D layer transfer. In FIG. 3A, a graphene layer 320 (e.g. a single-crystalline graphene layer) is fabricated on a substrate 305 (e.g., a 6″ SiC wafer). The graphene layer 320 is transferred to a growth substrate 310 to function as a release layer as seen in FIG. 3B. Alternatively, any other type of release layer or release layer formation process described herein can also be used.

FIG. 3C shows that a GaAs solar cell 330 is fabricated on the graphene layer 320 via epitaxial growth seeded by the growth substrate 310. In FIG. 3D, a stressor layer 340 is formed on the GaAs solar cell 330 to facilitate subsequent layer transfer. A tape layer 345 is disposed on the stressor 340 to help handle the layer transfer as seen in FIG. 3E.

After release from the growth substrate 310, the solar cell 330 becomes free standing and can be processed via at least two options. In one option, as illustrated in FIG. 3F, the solar cell 330 can be placed on metal 350a to form a first module 370a for subsequent module fabrication. The solar cell 330 can be attached to the metal 350a via direct bonding or any other techniques known in the art. The module fabrication of the first module 370a can include bonding the first module 370a to a second module 370b, which includes a second solar cell 360 disposed on a second metal 350b. The second module 370b can be fabricated using substantially the same method as illustrated in FIGS. 3A-3E.

In the second option, as illustrated in FIG. 3G, the free standing solar cell 330, together with the stressor layer 340 and the tape layer 345, form a lightweight and flexible solar cell assembly 380 in their own. This flexible solar cell assembly 380 can be easily integrated into other systems, including power electronic devices and wearable electronic systems.

Methods of Fabricating Multi-Junction Solar Cells

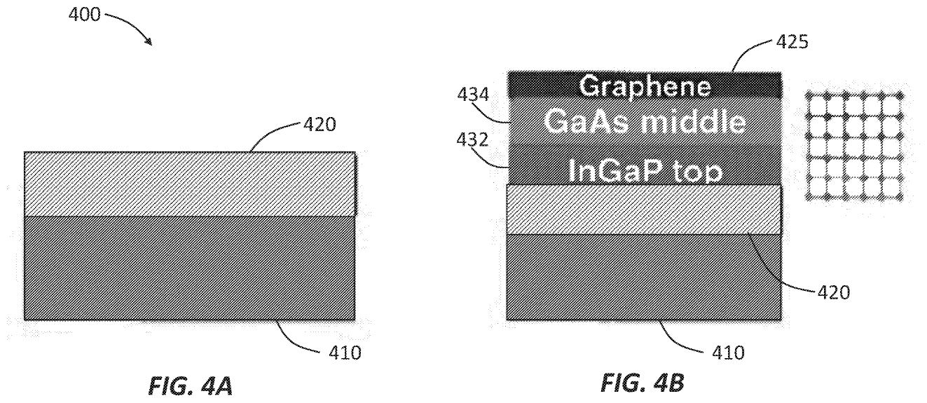

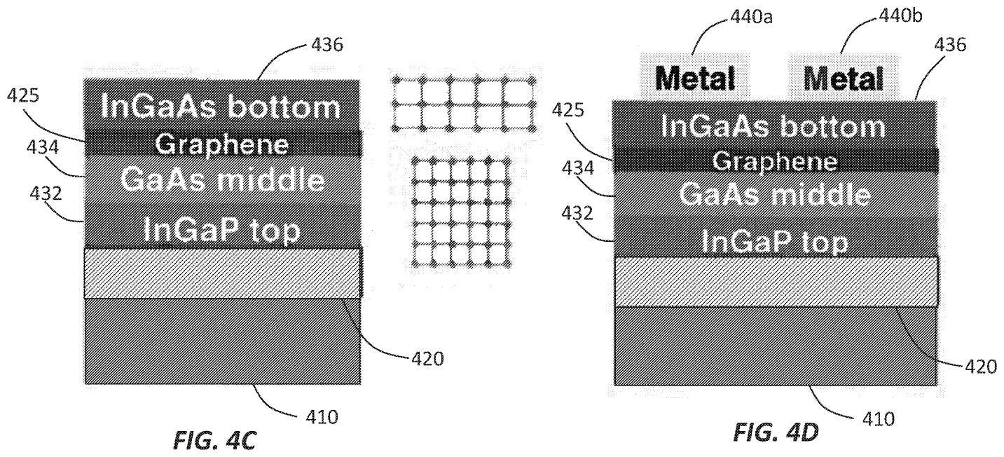

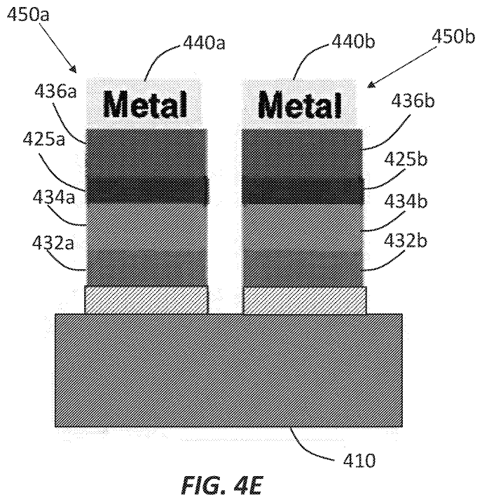

FIGS. 4A-4E illustrate a method 400 of fabricating multi junction solar cells using remote epitaxy and 2D layer transfer. The method 400 starts by disposing or forming a release layer 420 on a growth substrate 410, as shown in FIG. 4A. FIG. 4B shows that three material layers are deposited on the release layer 420, including an InGaP layer 432, a GaAs layer 434 on the InGaP layer 432, and a second release layer 425 (e.g., graphene or any other material described herein) on the GaAs layer 434. The InGaP layer 432 can be fabricated epitaxially using the growth substrate 410 as the seed. The GaAs layer 434 is lattice matched to the InGaP layer 432 and therefore can be epitaxially grown using the InGaP layer 432 as the seed.

FIG. 4C shows that an InGaAs layer 436 is deposited on the second release layer 425. The second release layer 425 can help lattice-matching during the fabrication of the InGaAs layer 436. Metal contacts 440a and 440b are then formed on the InGaAs layer 436 for electrical conduction, as shown in FIG. 4D. In FIG. 4E, the stack of InGaP layer 432, the GaAs layer 434, the second release layer 425, and the InGaAs layer 435 are etched into two solar cell mesas 450a and 450b, each of which is underneath a respective metal contact 440a and 440b. The first solar cell mesa 450a includes a first InGaP layer 432a, a first GaAs layer 434a, a first portion 425a of the second release layer 425, and a first InGaAs layer 435a. The second solar cell mesa 450b includes a second InGaP layer 432b, a second GaAs layer 434b, a second portion 425b of the second release layer 425, and a second InGaAs layer 435b.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method of fabricating a photovoltaic (PV) device, the method comprising:
forming a release layer comprising a two-dimensional (2D) material on a first substrate having a first lattice constant;
epitaxially growing a first PV layer on the release layer using the first substrate as a seed, the first PV layer having a second lattice constant substantially equal to the first lattice constant of the first substrate;
removing the first PV layer from the release layer; and
epitaxially growing a second PV layer on the release layer.

2. The method of claim 1, wherein forming the release layer comprises forming a graphene monolayer on the first substrate.

3. The method of claim 2, wherein forming the graphene monolayer comprises:
fabricating the graphene monolayer on a second substrate; and
transferring the graphene monolayer from the second substrate to the first substrate.

4. The method of claim 1, wherein epitaxially growing the first PV layer comprises:
epitaxially growing a first emitter layer on the release layer; and
epitaxially growing a first base layer on the first emitter layer.

5. The method of claim 4, further comprising:
placing the first base layer in contact with a host substrate such that the first emitter layer is oriented to receive incident light for generating electricity.

6. The method of claim 1, wherein epitaxially growing the first PV layer comprises epitaxially growing a single-junction PV cell.

7. The method of claim 6, wherein the single-junction PV cell comprises at least one of a GaAs PV cell or an InP PV cell.

8. The method of claim 1, wherein epitaxially growing the first PV layer comprises epitaxially growing a multi junction PV cell.

9. The method of claim 8, wherein the multi junction PV cell comprises at least one of a GaAs/InGaP double-junction PV cell, a GaInAsP/GaInAs double-junction PV cell, an InGaAs/GaAs/InGaP triple-junction PV cell, an InGaP/GaAs/GaInAsP/GaInAs four-junction PV cell, or an InP/InGaAs double-junction PV cell.

10. The method of claim 1, further comprising:
transferring the first PV layer to a host substrate; and
transferring the second PV layer onto the first PV layer via at least one of wafer bonding or grid bonding.

11. The method of claim 1, wherein removing the first PV layer comprises:
forming a metal stressor on the first PV layer; and
disposing the metal stressor in contact with the host substrate.

12. The method of claim 1, wherein removing the first PV layer comprises:
bonding the first PV layer to an electrode layer.

13. The method of claim 1 wherein removing the first PV layer comprises:
forming an electrode on the first PV layer;
disposing a flexible tape on the electrode; and
pulling the first PV layer and the electrode off the release layer with the flexible tape so as to form a flexible PV cell.

14. A PV device formed by the method of claim 1.

15. A method of fabricating a photovoltaic (PV) device, the method comprising:
forming a graphene monolayer on a first substrate having a first lattice constant;
epitaxially growing a first emitter layer on the release layer using the first substrate as a seed;
epitaxially growing a first base layer on the first emitter layer to form a first PV layer, the first PV layer having a second lattice constant substantially equal to the first lattice constant of the first substrate;
transferring the first PV layer to a host substrate such that the first emitter layer is oriented to receive incident light for generating electricity; and
epitaxially growing a second PV layer on the release layer.
